(19) United States
(12) Patent Application Publication
(10) Pub. No.: US 2015/0255353 A1
(43) Pub. Date: Sep. 10, 2015

(54) FORMING SOURCE/DRAIN REGIONS WITH SINGLE RETICLE AND RESULTING DEVICE

(71) Applicant: GLOBALFOUNDRIES Inc., Grand Cayman (KY)

(72) Inventors: Jing WAN, Malta, NY (US); Andy WEI, Dresden (DE); Jinping LIU, Ballston Lake, NY (US); Xiang HU, Clifton Park, NY (US); Dae-han CHOI, Loudonville, NY (US); Dae Geun YANG, Watervliet, NY (US); Churamani GAIRE, Clifton Park, NY (US); Akshey SEHGAL, Malta, NY (US)

(73) Assignee: GLOBALFOUNDRIES Inc., Grand Cayman (KY)

(21) Appl. No.: 14/197,267

(22) Filed: Mar. 5, 2014

(51) Int. Cl. H01L 21/8238; H01L 27/092

(52) U.S. Cl. CPC H01L 21/823814; H01L 27/0924; H01L 21/823821

(57) ABSTRACT

Methods for forming FinFET source/drain regions with a single reticle and the resulting devices are disclosed. Embodiments may include forming a first fin and a second fin above a substrate, forming a gate crossing over the first fin and the second fin, removing portions of the first fin and the second fin on both sides the gate, forming silicon phosphorous tops on the first fin and the second fin in place of the portions, removing the silicon phosphorous tops on the first fin, and forming silicon germanium tops on the first fin in place of the silicon phosphorous tops.

### TECHNICAL FIELD

The present disclosure relates to fabrication of source/drain regions of field-effect transistors (FETs). The present disclosure is particularly applicable to forming source/drain regions of FETs using a single reticle for 20 nanometer (nm) technology nodes and beyond.

### BACKGROUND

Current FET fabrication uses two reticles to grow embedded silicon germanium (eSiGe) and silicon phosphorous (SiP) source/drain regions separately for p-type and n-type FETs, respectively. Another reticle is used for the n-type FET source/drain implantation. The use of multiple reticles not only increases the production cost but also escalates the difficulty of the process. Further, the misalignment of various masks creates bumps on the gate, which can be an issue during the dummy gate removal step in a replacement metal gate (RMG) process scheme.

A need therefore exists for methodology enabling formation of source/drain regions for FETs using a single reticle, and the resulting device.

### SUMMARY

An aspect of the present disclosure is a method for forming FET source/drain regions using a single reticle.

Another aspect of the present disclosure is a FET formed using a single reticle for the formation of the source/drain regions.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including forming a first fin and a second fin above a substrate, forming a gate crossing over the first fin and the second fin, removing portions of the first fin and the second fin on both sides the gate, forming silicon phosphorous tops on the first fin and the second fin in place of the portions, removing the silicon phosphorous tops on the first fin, and forming silicon germanium tops on the first fin in place of the silicon phosphorous tops.

An aspect of the present disclosure includes the first fin being part of a p-type FinFET and the second fin being part of an n-type FinFET. Another aspect includes forming a mask over the substrate, the first fin, the second fin, and the gate prior to removing the portions of the first fin and the second fin, and removing a first portion of the mask to expose the portions of the first fin and the second fin. Yet another aspect includes forming the mask to a thickness of 10 nm. Still a further aspect includes forming a cap over the gate prior to forming the mask, forming the mask over the cap, and removing the mask over the gate and part of the cap during removal of the first portion of the mask. Yet another aspect includes forming a mask over the silicon phosphorous tops of the first fin and the second fin, and removing a first portion of the mask to expose the silicon phosphorous tops on the first fin prior to removing the silicon phosphorous tops on the first fin. A further aspect includes forming the mask to a thickness of 3 nm. An additional aspect includes forming a diffusion liner on the first fin and the second fin after removing the portions of the first fin and the second fin.

Another aspect of the present disclosure is a method including forming a first fin and a second fin above a substrate, forming a gate crossing over the first fin and the second fin, removing portions of the first fin and the second fin on both sides of the gate, forming silicon germanium tops on the first fin and the second fin in place of the portions, removing the silicon germanium tops on the second fin, and forming silicon phosphorous tops on the second fin in place of the silicon germanium tops.

An aspect of the present disclosure includes the first fin being part of a p-type FinFET and the second fin being part of an n-type FinFET. Another aspect includes forming a mask over the substrate, the first fin, the second fin, and the gate prior to removing the portions of the first fin and the second fin, and removing a first portion of the mask to expose the portions of the first fin and the second fin. Yet another aspect includes forming the mask to a thickness of 10 nm. Yet another aspect includes forming a cap over the gate prior to forming the mask, forming the mask over the cap, and removing the mask over the gate and part of the cap during removal of the first portion of the mask. A further aspect includes forming a mask over the silicon germanium tops of the first fin and the second fin, and removing a first portion of the mask to expose the silicon germanium tops on the second fin prior to removing the silicon germanium tops on the second fin. Still another aspect includes forming the mask to a thickness of 3 nm. A further aspect includes the silicon phosphorous tops of the second fin being smaller than the silicon germanium tops of the first fin.

Another aspect of the present disclosure is a device including: a substrate, a first fin and a second fin extending up from the substrate, and a gate crossing over the first fin and the second fin above the substrate, the gate having a planar top surface, wherein top ends of the first fin on both sides of the gate comprise silicon germanium, and top ends of the second fin on both sides of the gate comprise silicon phosphorous.

Aspects include a diffusion liner below the top ends of the first fin and the second fin. A further aspect includes the silicon germanium top ends of the first fin being larger than the silicon phosphorous top ends of the second fin. Still another embodiment includes the silicon germanium top ends of the first fin including a high-doped germanium first layer and a low-doped germanium second layer, and the low-doped germanium second layer also being below the silicon phosphorous top ends of the second fin.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawings and in which like reference numerals refer to similar elements and in which:

FIGS. 1A through 1C schematically illustrate the first step of a method for forming a p-type and n-type FinFET structure in accordance with an exemplary embodiment, with FIGS. 1A and 1B illustrating cross-sectional views along lines A-A and B-B, respectively, of the three-dimensional view of FIG. 1C;

FIGS. 2A through 11A and 2B through 11B schematically illustrate cross-sectional views, along lines A-A and B-B, respectively, of the three-dimensional view of FIG. 1C for the remaining steps of the method for forming a p-type and n-type FinFET structure, in accordance with the exemplary embodiment; and

FIGS. 12A through 17A and 12B through 17B schematically illustrate cross-sectional views along lines A-A and C-C, respectively, of the three-dimensional view of FIG. 1C for a method for forming a p-type and n-type FinFET structure, in accordance with an alternative exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of increased production cost and bumps formed on gates attendant upon forming source/drain regions for FETs using multiple reticles. In accordance with embodiments of the present disclosure, a process uses a single reticle to form source/drain regions of a FET.

Methodology in accordance with an embodiment of the present disclosure includes forming a first fin and a second fin above a substrate, and forming a gate crossing over the first fin and the second fin. Portions of the first fin and the second fin on both sides of the gate are removed and silicon phosphorous tops are formed on the first fin and the second fin in place of the portions. The silicon phosphorous tops on the first fin are removed and silicon germanium tops are formed on the first fin in place of the silicon phosphorous tops. Alternatively, the process may be reversed such that silicon germanium tops are formed first and replaced with silicon phosphorous tops.

Although the below examples are focused on forming p-type and n-type source/drain regions for FinFETs, the process may be modified for forming p-type and n-type source/drain regions for planar FETs without changing the spirit and scope of the process without any undue burden.

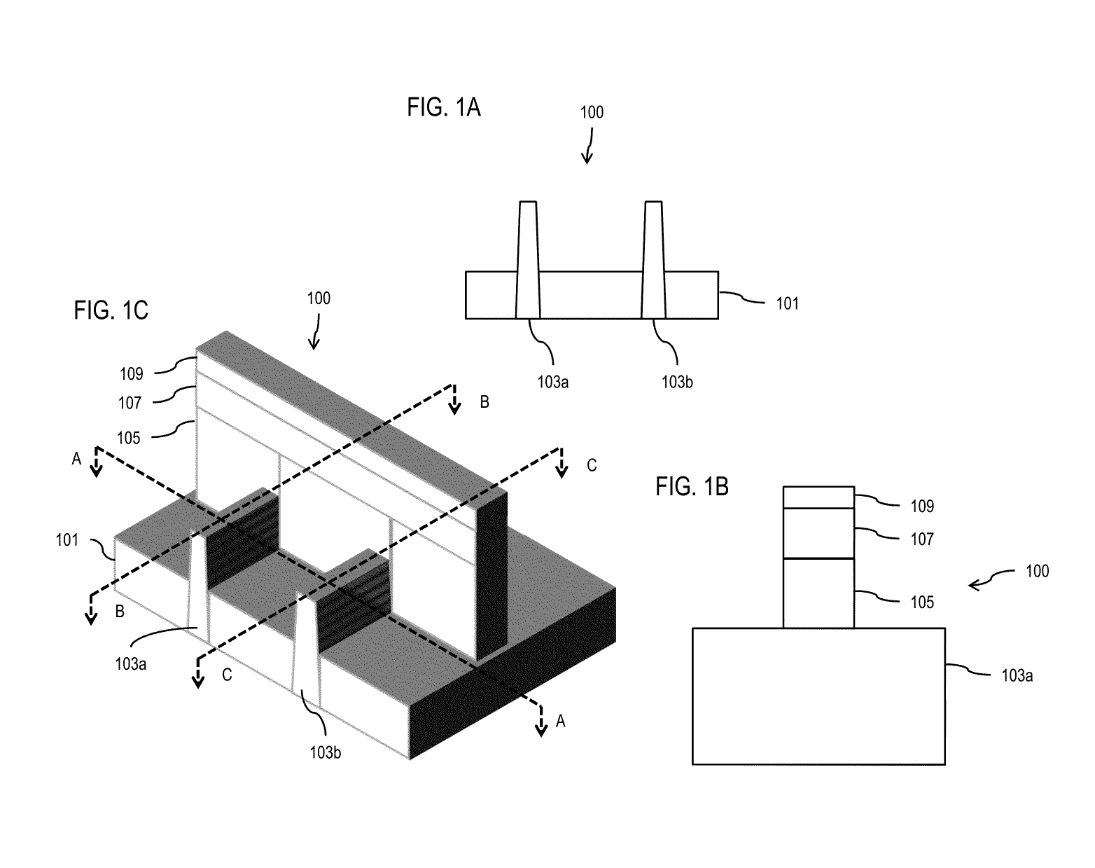

Adverting to FIGS. 1A through 1C, a method for forming FinFET source/drain regions with a single reticle, according to an exemplary embodiment, begins with the structure 100. As illustrated in the three-dimensional schematic view of FIG. 1C, the structure 100 includes a shallow trench isolation (STI) area 101. The STI area 101 may be formed of any material that may constitute an STI area. Extending up from the STI area 101 are two fins 103a and 103b. The fins 103a and 103b may be formed of any material that may form, or be a precursor for forming, a fin to form a FinFET, such as silicon (Si). The fins 103a and 103b pass through and, therefore, are partially covered by a dummy gate 105. The dummy gate 105 may be formed of any material that may constitute a dummy gate, such as amorphous Si (a-Si). Above the dummy gate 105 is a first cap 107. The first cap 107 may be formed of a nitride, such as silicon nitride (SiN), and may have a thickness of 10 to 100 nm, such as 55 nm. Above the first cap 107 is a second cap 109. The second cap 109 may be formed of an oxide, such as silicon oxide (SiO₂), and may have a thickness of 10 to 100 nm, such as 23 nm. FIGS. 1A through 11A illustrate a cross section of the structure 100 along the A-A line illustrated in FIG. 1C. FIGS. 1B through 11B illustrate a cross section of the structure 100 along the B-B line illustrated in FIG. 1C.

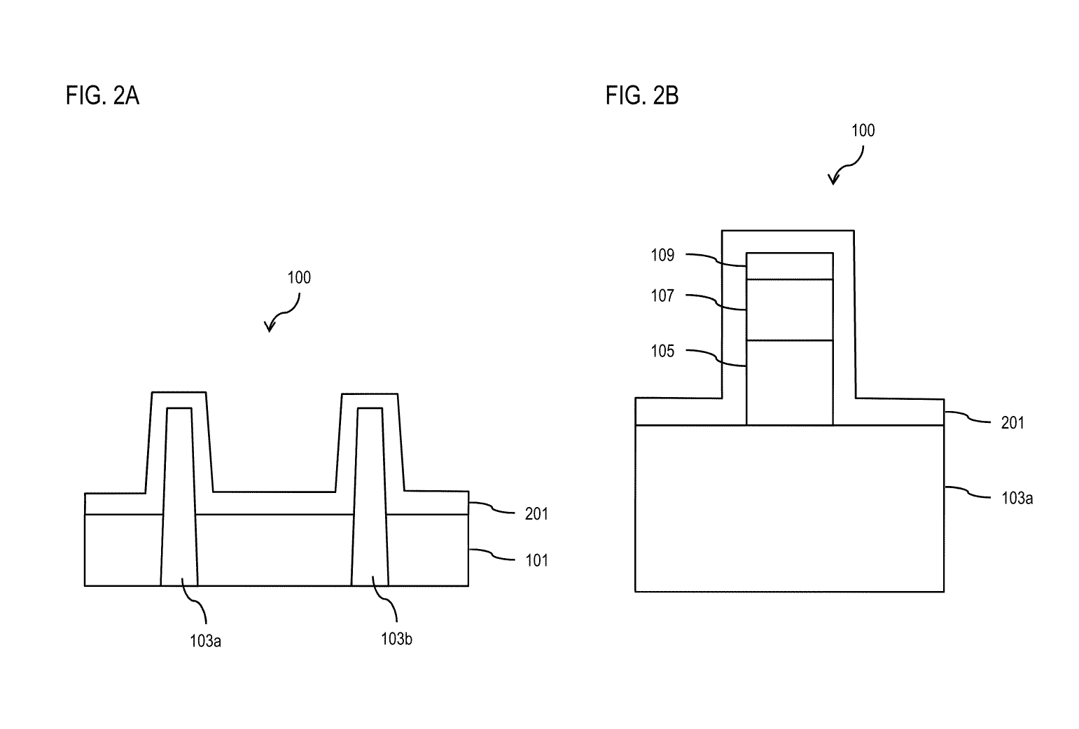

Adverting to FIGS. 2A and 2B, a mask 201 is then formed over the structure 100. The mask 201 may be formed of any material that acts as a mask, such as silicon nitride (SiN), and may be formed to a thickness of 5 to 50 nm, such as 10 nm. The mask 201 may also be formed according to any conventional processing, such as deposition.

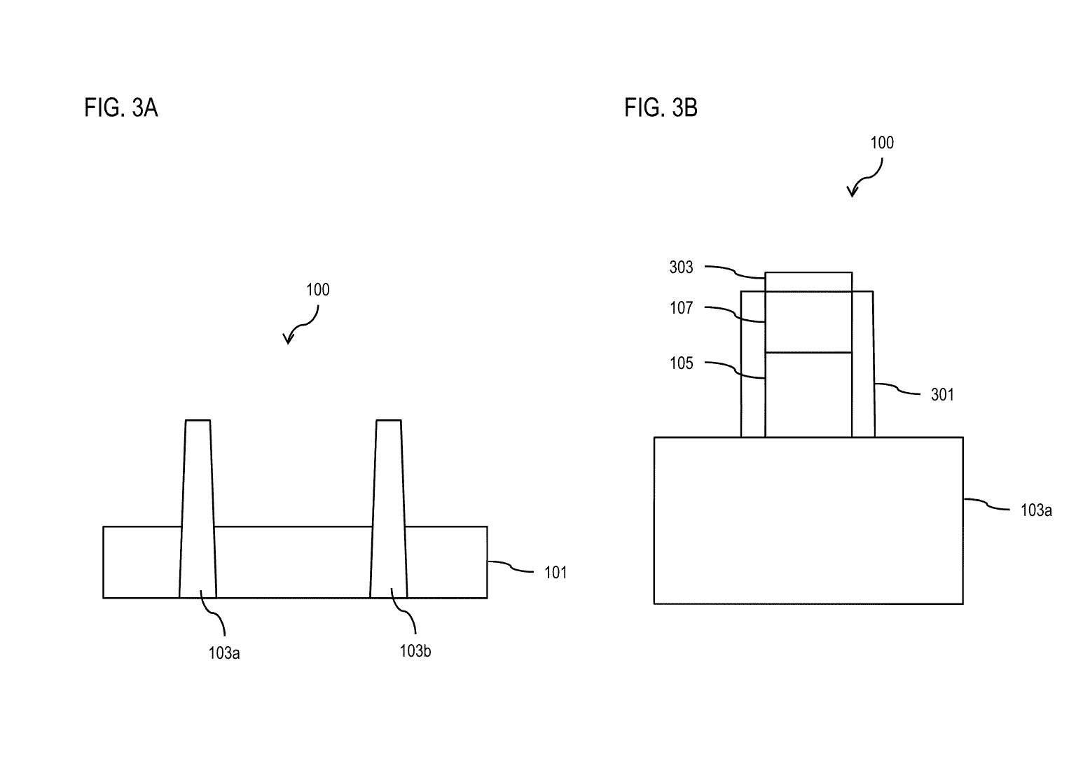

The mask 201 is then partially removed to reveal the fins 103a and 103b, as illustrated in FIGS. 3A and 3B, with a remaining portion 301 of the mask 201 on sides of the dummy gate 105. The mask 201 may be partially removed according to any conventional processing depending on the material used to form the mask 201, such as a dry etch. In partially removing the mask 201, part of the second cap 109 may also be removed, forming a partial cap 303, depending on the process used to remove the mask 201 and the material used to form the second cap 109.

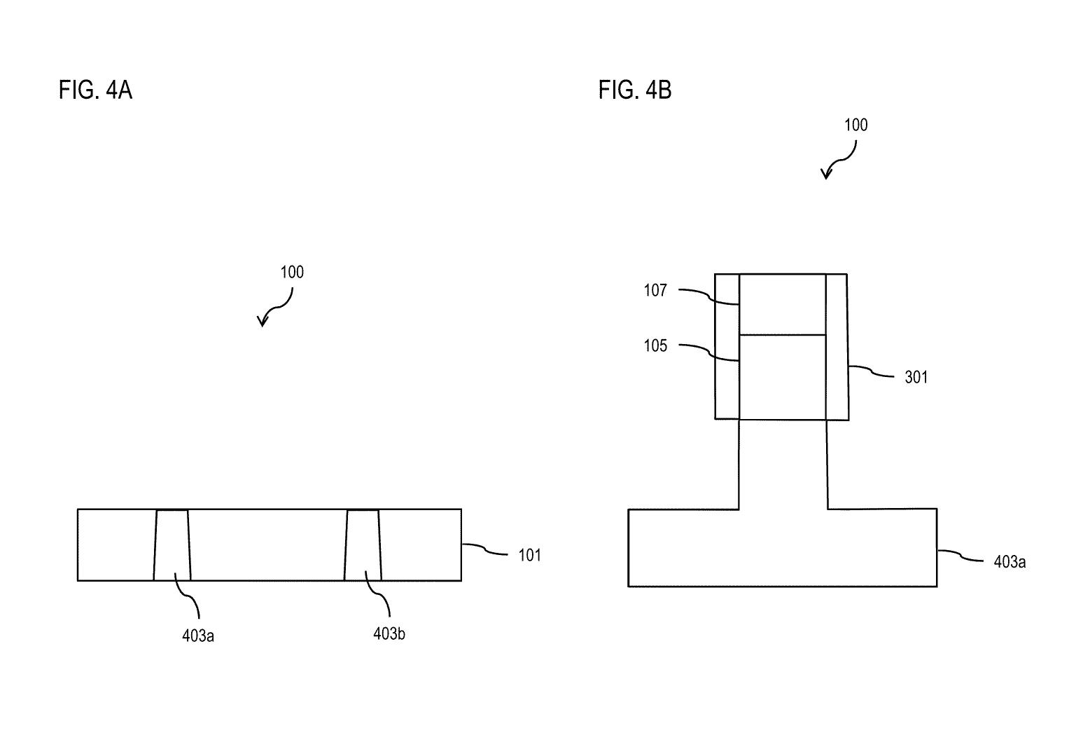

Next, portions of the fins 103a and 103b are removed to form partial fins 403a and 403b, as illustrated in FIGS. 4A and 4B. As illustrated in FIG. 4A, tops of the fins 103 and 103b may be removed down to the STI area 101. The fins 403a and 403b may be formed be etching back the fins 103a and 103b, such as by using a Si etch. During formation of the partial fins 403a and 403b, the remaining partial cap 303 may be removed down to the first cap 107.

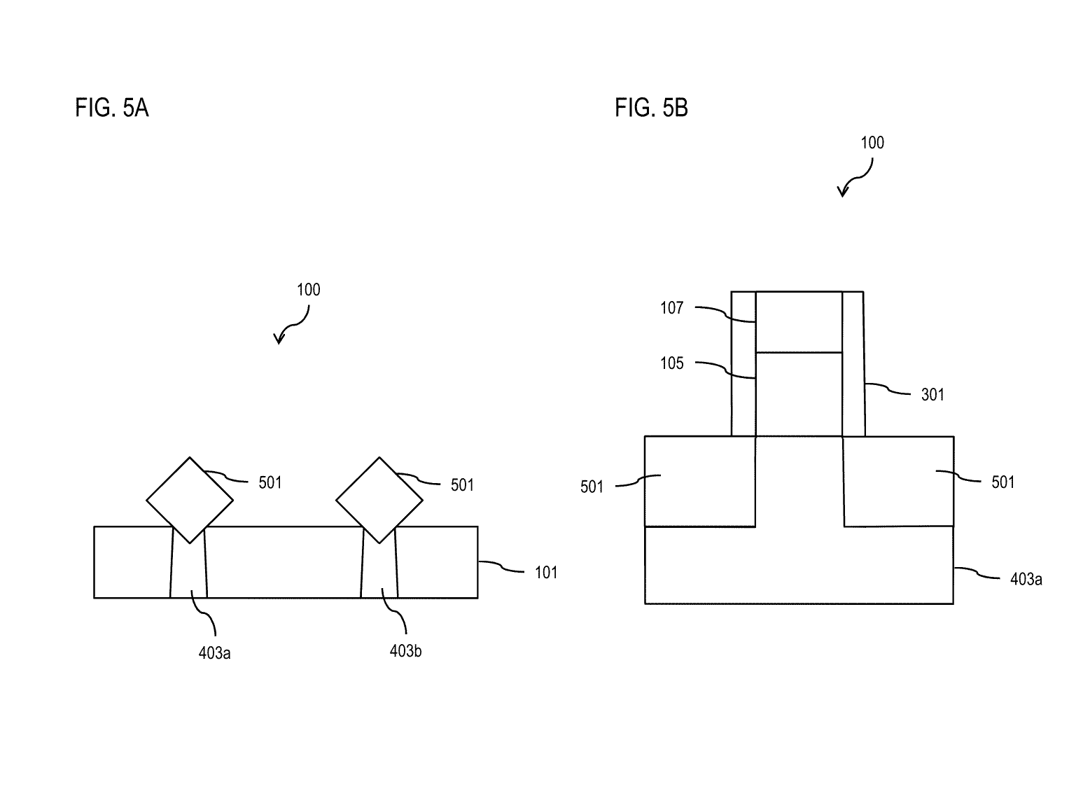

Adverting to FIGS. 5A and 5B, n-type source/drain regions 501 are then formed above the partial fins 403a and 403b. The n-type source/drain regions 501 may be formed by epitaxy and may be formed of silicon phosphorous (SiP). After forming the n-type source/drain regions 501, the n-type source/drain regions 501 may be implanted with one or more dopants. Source/drain implantation at this step may further save one mask.

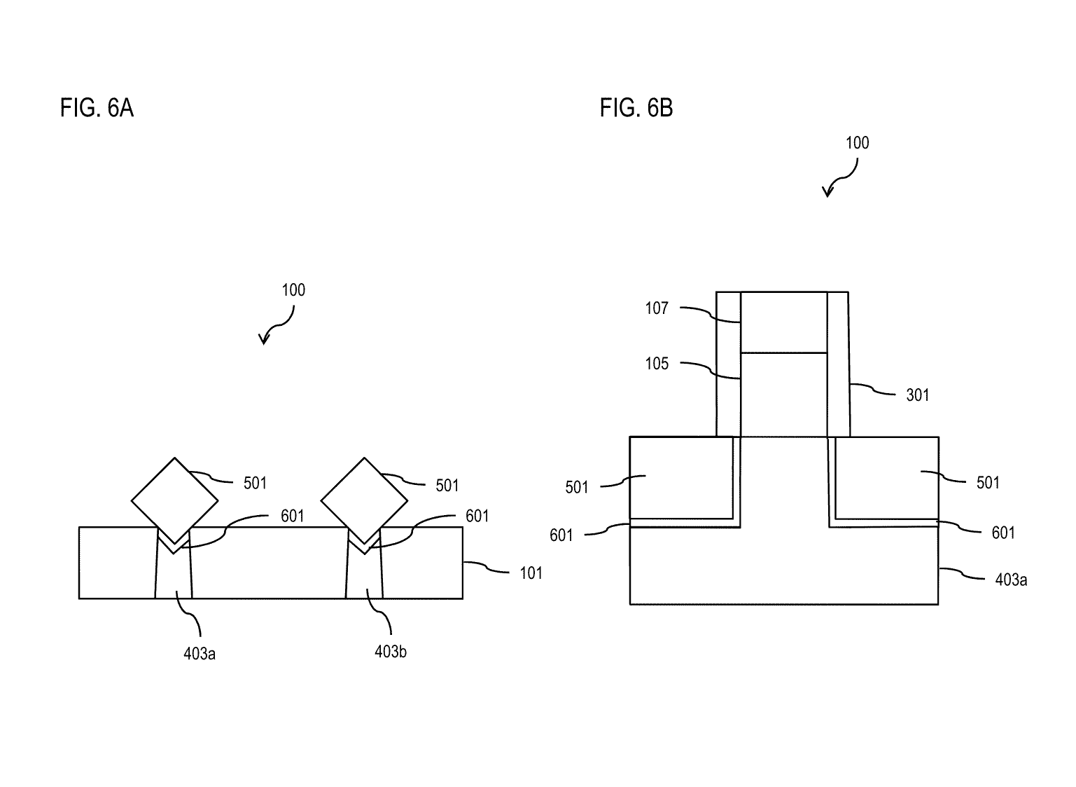

Alternatively, prior to forming the n-type source/drain regions 501, a liner 601 may be formed above the partial fins 403a and 403b, as illustrated in FIGS. 6A and 6B. The liner 601 may be formed of silicon carbide (SiC). The liner 601 may be formed before forming the n-type source/drain regions 501 to prevent diffusion of phosphorous or dopants into the surrounding structure, such as the channel, during subsequent processing steps.

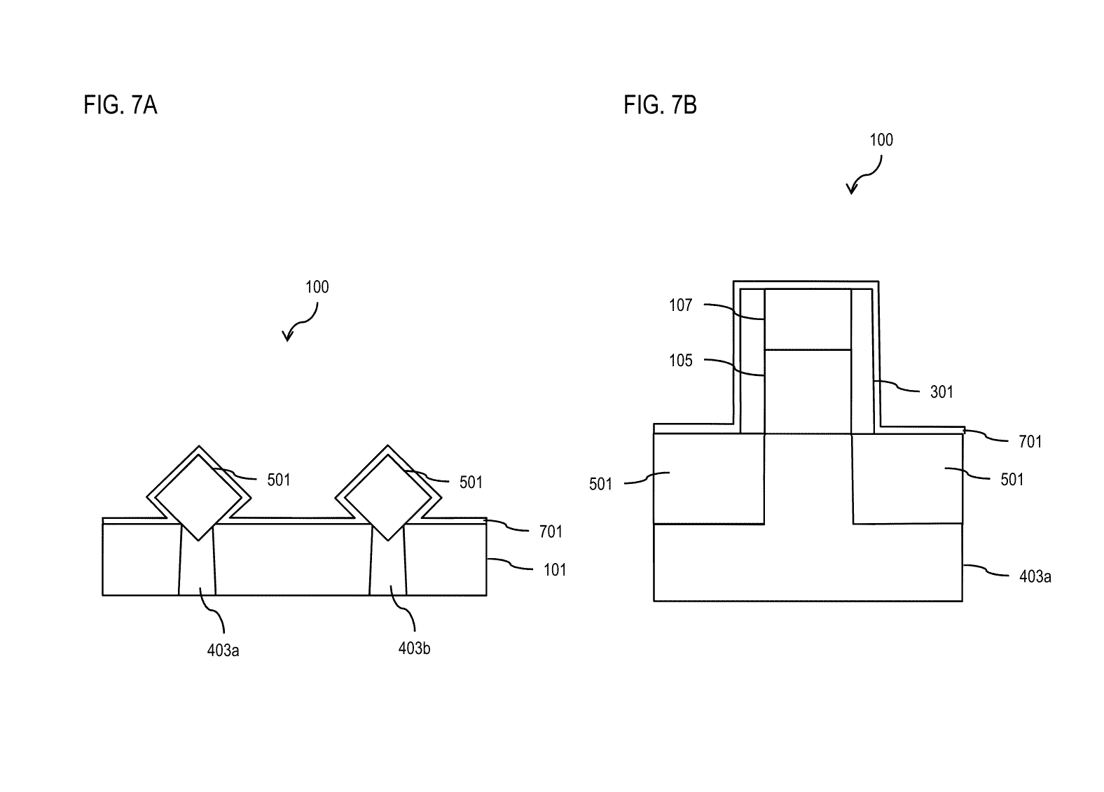

Illustrated in FIGS. 7A and 7B, a mask 701 is formed over the structure 100, including over the n-type source/drain regions 501. The mask 701 may be formed of any conventional material that may act as a mask for the subsequent processing steps, such as a nitride (e.g., SiN), SiOC, or SiO₂, and may be formed to a thickness of 1 to 10 nm, such as 3 nm.

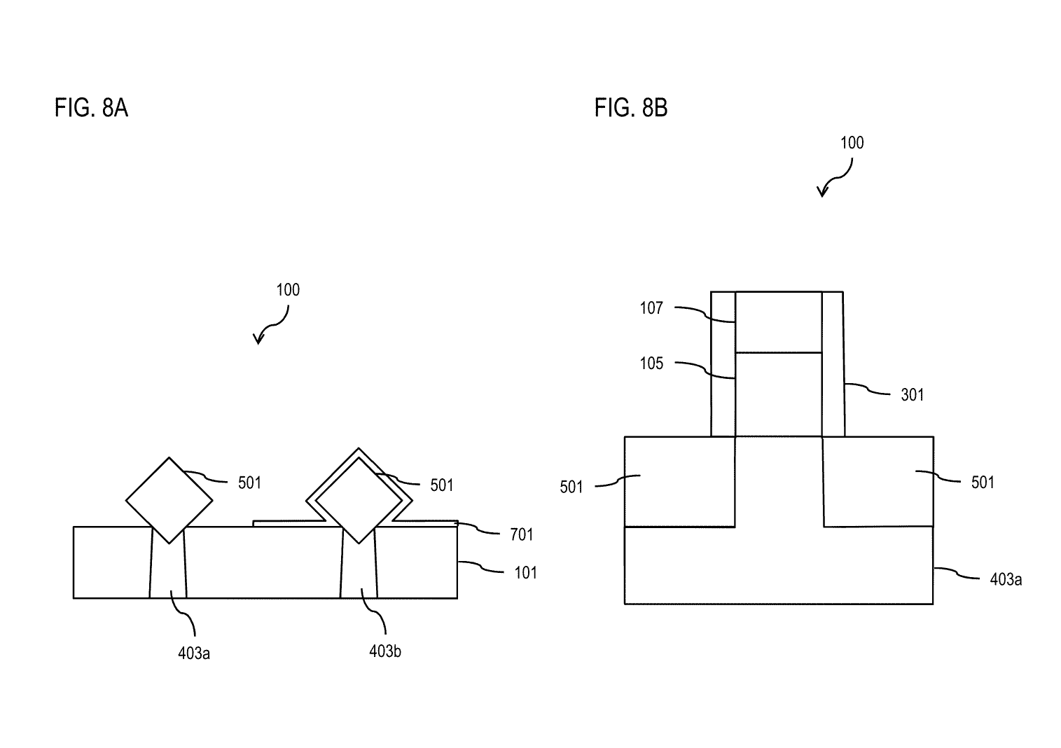

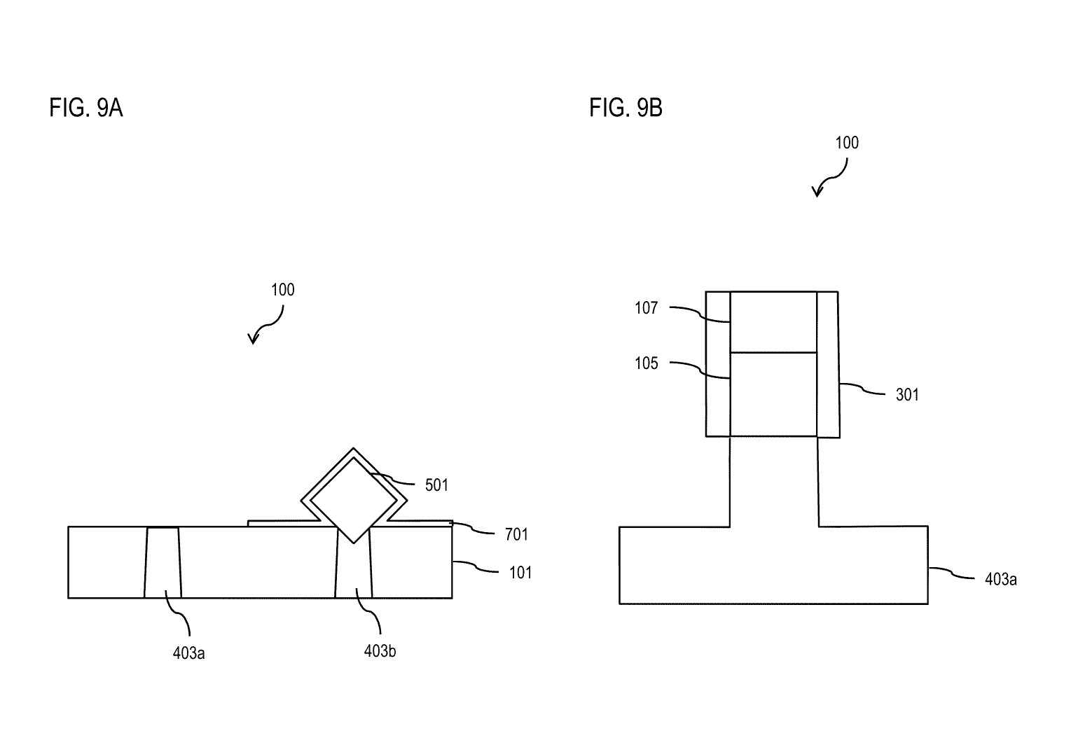

Adverting to FIGS. 8A and 8B, the mask 701 over the fin 403a is removed according to any processing, such as lithography and etching. Then, the n-type source/drain regions 501 over the fin 403a are removed, as illustrated in FIGS. 9A and 9B. Although illustrated as two separate steps, the mask 701 and the n-type source/drain regions 501 over the fin 403a may be removed in a single process step, such as by using the same lithography and etch step, or the same lithography and multiple etch steps.

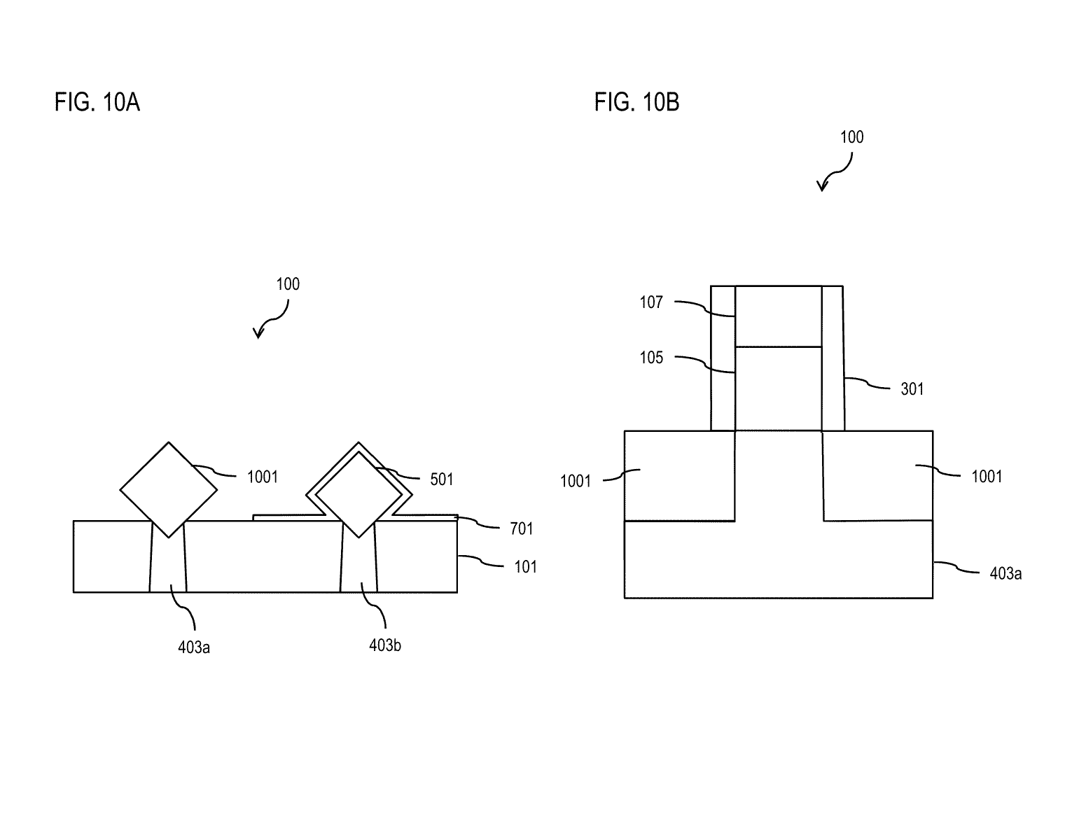

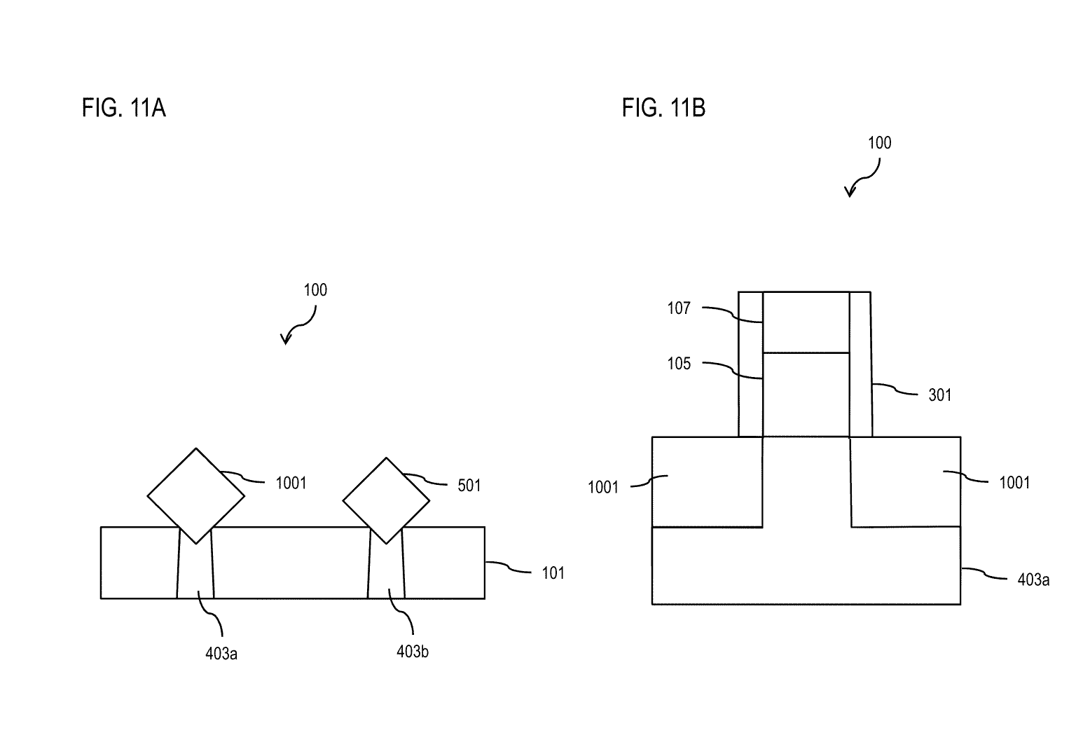

Next, p-type source/drain regions 1001 are formed above the partial fin 403a, as illustrated in FIGS. 10A and 10B. The p-type source/drain regions 1001 may be formed by epitaxy and may be formed of silicon germanium (SiGe). After forming the p-type source/drain regions 1001, the p-type source/drain regions 1001 may be implanted with one or more dopants, such as boron. Source/drain implantation at this step may further save one mask. The remaining mask 701 may then be removed, as illustrated in FIGS. 11A and 11B.

The combination of the p-type source/drain regions 1001 and the partial fin 403a forms a p-type FinFET, and the combination of the n-type source/drain regions 501 and the partial fin 403b forms an n-type FinFET. The above process permits the formation of the p-type and n-type FinFETs using one reticle, which simplifies the masking steps and process as a whole, in addition to avoiding the formation of bumps over the dummy gate 105. The n-type source/drain regions 501 may be smaller than the p-type source/drain regions 1001 such that the larger volume of the p-type source/drain regions 1001 can completely replace the n-type source/drain regions 501. The smaller volume of the n-type source/drain regions 501 may also make the lithography for forming the n-type source/drain regions 501 easier. Further, the phosphorous in the SiP may diffuse during the eSiGe epitaxy into the surrounding structure. Such diffusion may be controlled or limited by reducing the thermal budget during the eSiGe epitaxy and/or by forming the liner 601.

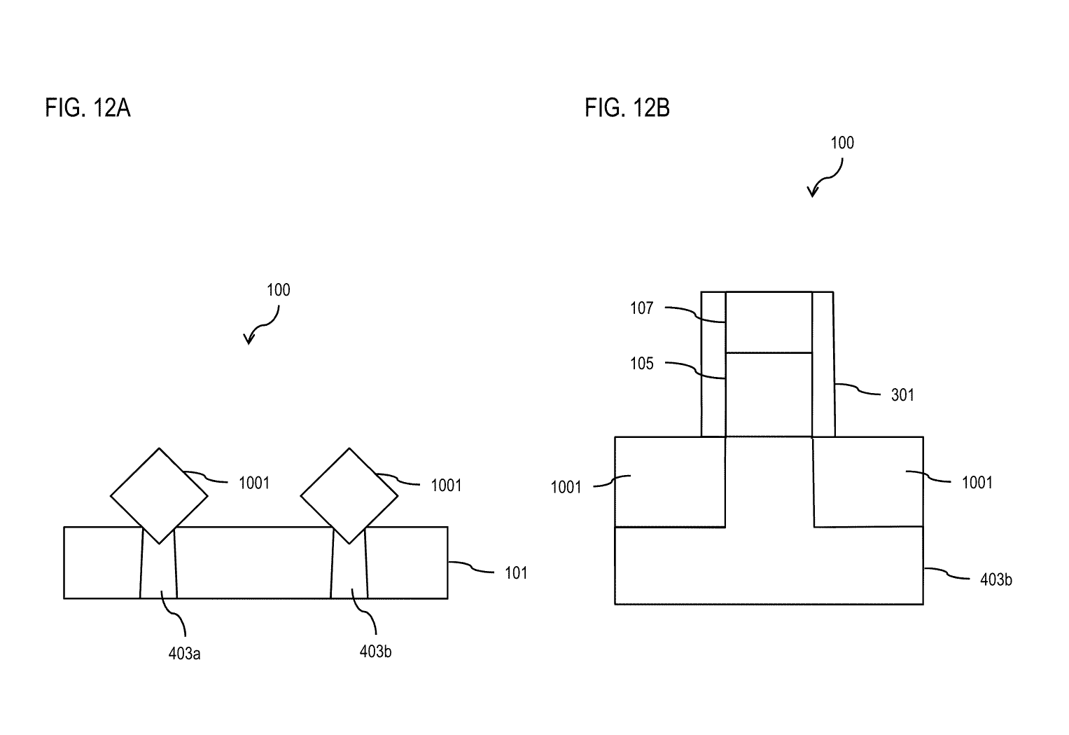

Adverting to FIGS. 12A and 12B, which schematically illustrate cross-sectional views along lines A-A and C-C, respectively, of the three-dimensional view of FIG. 1C, a method for forming FinFET source/drain regions with a single reticle, according to an alternative exemplary embodiment, begins with the structure 100 as illustrated in FIGS. 11A and 11B; however, p-type source/drain regions 1001 are first formed above the partial fins 403a and 403b. The p-type source/drain regions 1001 may be formed by epitaxy and may be formed of SiGe. After forming the p-type source/drain regions 1001, the p-type source/drain regions 1001 may be doped with one or more implants, such as boron. Source/drain implantation at this step may further save one mask.

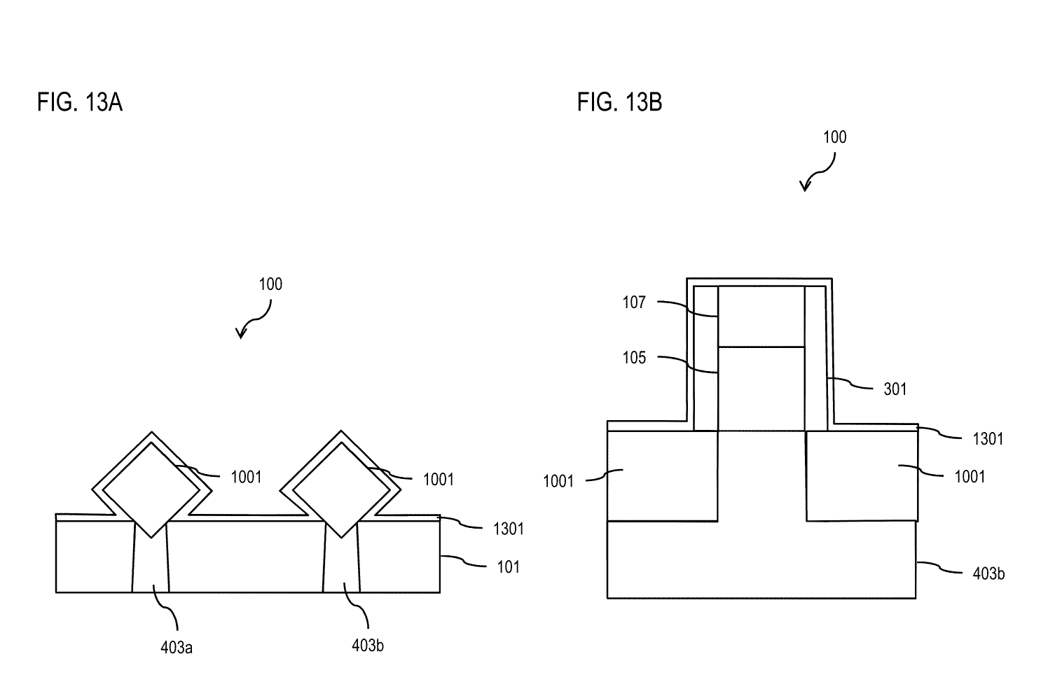

Illustrated in FIGS. 13A and 13B, a mask 1301 is formed over the structure 100, including over the p-type source/drain regions 1001. The mask 1301 may be the same as or similar to the mask 701, such that the mask 1301 may be formed of any conventional material that may act as a mask for the subsequent processing steps, such as a nitride (e.g., SiN), SiOC, or SiO₂, and may be formed to a thickness of 1 to 10 nm, such as 3 nm.

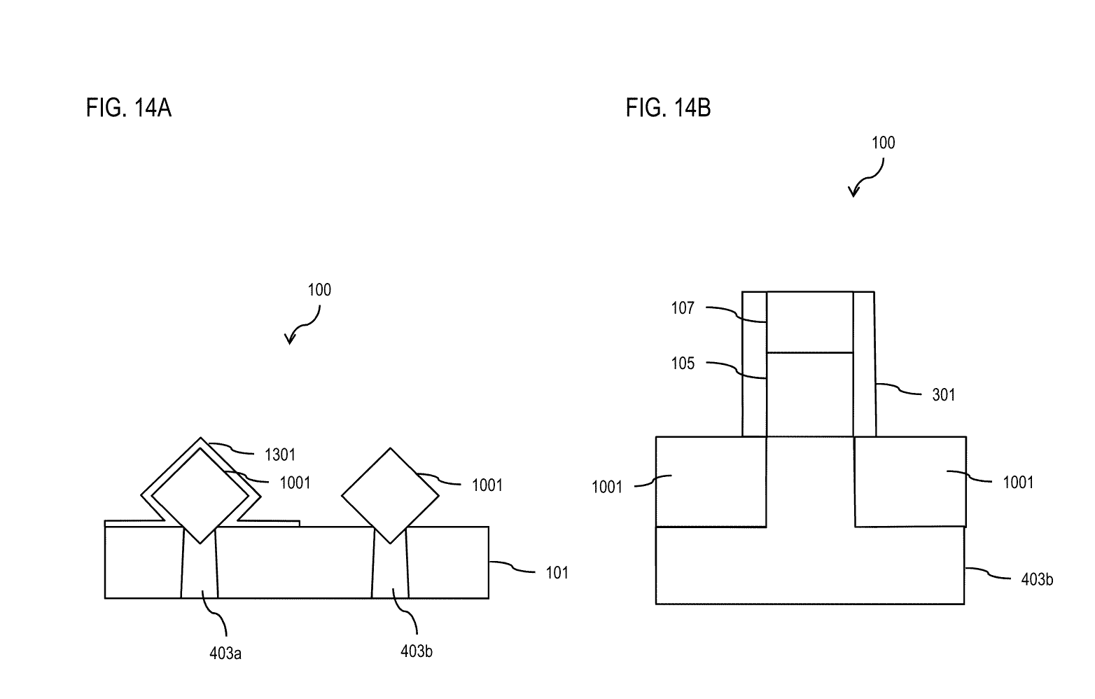

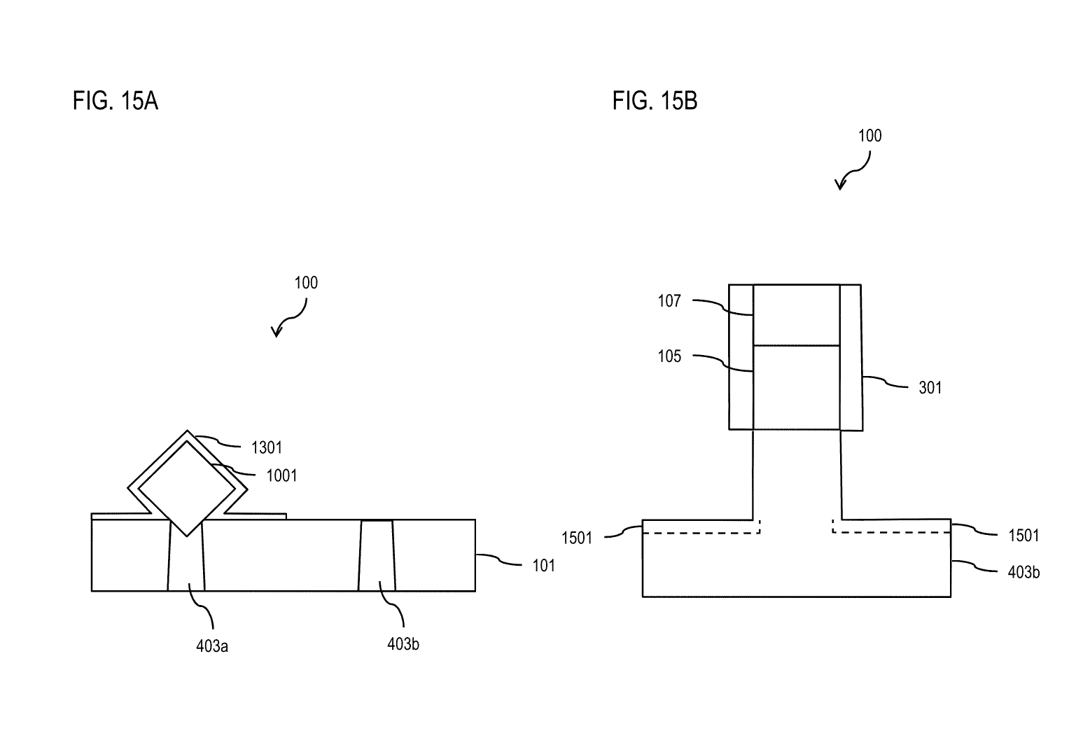

Adverting to FIGS. 14A and 14B, the mask 1301 over the fin 403b is removed according to any processing, such as lithography and etching. Then, the p-type source/drain regions 1001 over the fin 403b are removed, as illustrated in FIGS. 15A and 15B. Although illustrated as two separate steps, the mask 1301 and the p-type source/drain regions 1001 over the fin 403b may be removed in a single process step, such as by using the same lithography and etch step, or the same lithography and multiple etch steps. Because of the size of the p-type source/drain regions 1001 and subsequent process steps used to dope the p-type source/drain regions 1001, a residual dopant layer 1501 may remain that may have some dopant, such as boron (B), as well as low levels of germanium (Ge) that do not affect the final product.

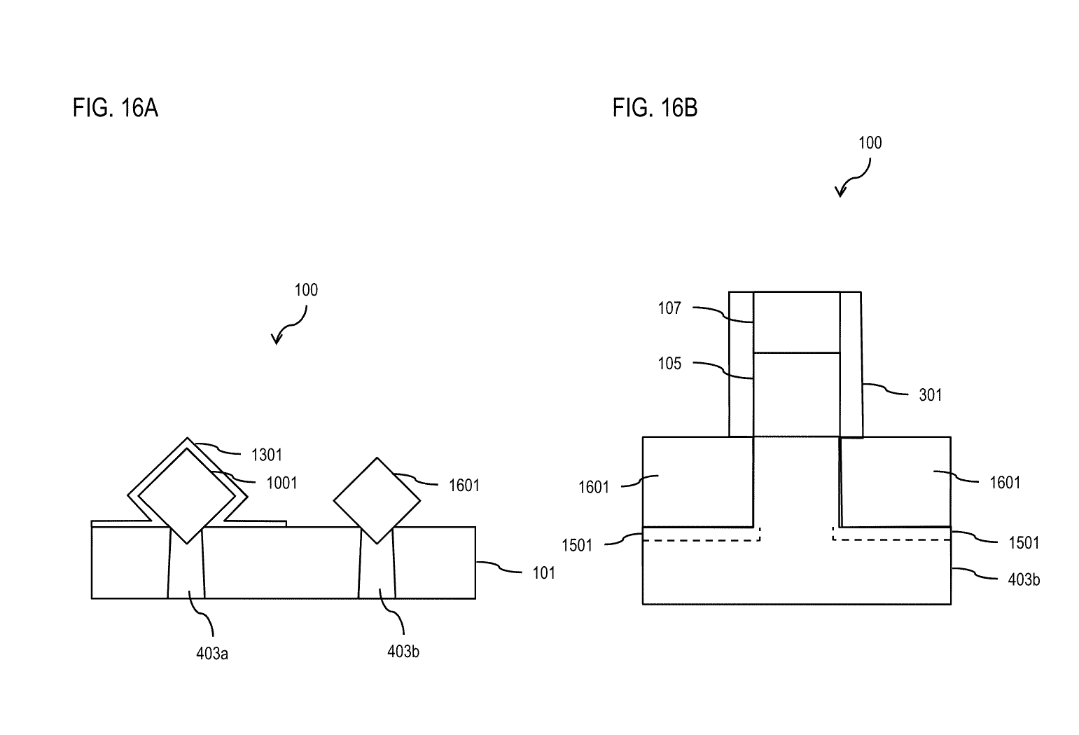

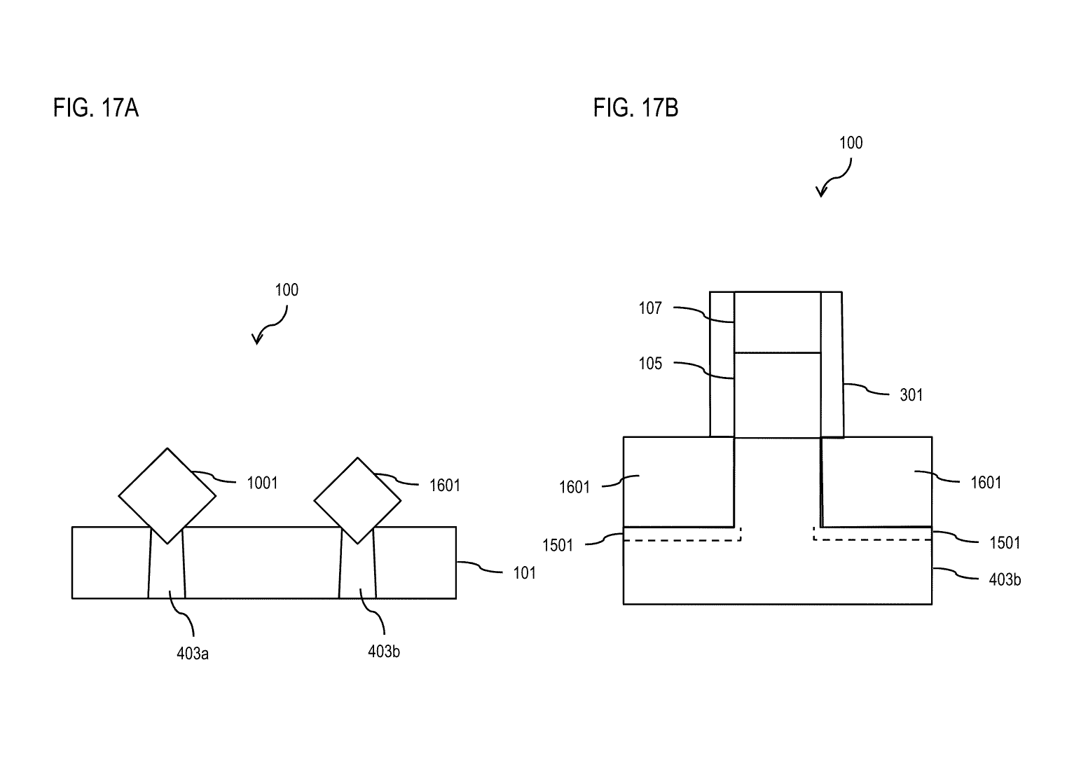

Next, n-type source/drain regions 1601 are formed above the partial fin 403b, as illustrated in FIGS. 16A and 16B. The n-type source/drain regions 1601 may be formed by epitaxy and may be formed of silicon phosphorous (SiP). After forming the n-type source/drain regions 1601, the n-type source/drain regions 1601 may be doped with one or more implants. Source/drain implantation at this step may further save one mask. The remaining mask 1301 may then be removed, as illustrated in FIGS. 17A and 17B.

As described above, the combination of the p-type source/drain regions 1001 and the partial fin 403a forms a p-type FinFET, and the combination of the n-type source/drain regions 1601 and the partial fin 403b forms an n-type FinFET. The above process permits the formation of the p-type and n-type FinFETs using one reticle, which simplifies the masking steps and process as a whole, in addition to avoiding the formation of bumps over the dummy gate 105.

The embodiments of the present disclosure achieve several technical effects, including source/drain regions of FETs formed without forming a bump over the gate, in addition to being formed with less complexity and cost. The present disclosure enjoys industrial applicability associated with the designing and manufacturing of any of various types of highly integrated semiconductor devices used in microprocessors, smart phones, mobile phones, cellular handsets, set-top boxes, DVD recorders and players, automotive navigation, printers and peripherals, networking and telecom equipment, gaming systems, and digital cameras.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming a first fin and a second fin above a substrate;
forming a gate crossing over the first fin and the second fin;
removing portions of the first fin and the second fin on both sides the gate;
forming silicon phosphorous tops on the first fin and the second fin in place of the portions;
removing the silicon phosphorous tops on the first fin; and
forming silicon germanium tops on the first fin in place of the silicon phosphorous tops.

2. The method according to claim 1, wherein the first fin is part of a p-type FinFET and the second fin is part of an n-type FinFET.

3. The method according to claim 1, further comprising:
forming a mask over the substrate, the first fin, the second fin, and the gate prior to removing the portions of the first fin and the second fin; and
removing a first portion of the mask to expose the portions of the first fin and the second fin.

4. The method according to claim 3, comprising:
forming the mask to a thickness of 10 nm.

5. The method according to claim 3, further comprising:
forming a cap over the gate prior to forming the mask;
forming the mask over the cap; and
removing the mask over the gate and part of the cap during removal of the first portion of the mask.

6. The method according to claim 1, further comprising:
forming a mask over the silicon phosphorous tops of the first fin and the second fin; and
removing a first portion of the mask to expose the silicon phosphorous tops on the first fin prior to removing the silicon phosphorous tops on the first fin.

7. The method according to claim 6, comprising:
forming the mask to a thickness of 3 nm.

8. The method according to claim 1, further comprising:
forming a diffusion liner on the first fin and the second fin after removing the portions of the first fin and the second fin.

9. A method comprising:
forming a first fin and a second fin above a substrate;
forming a gate crossing over the first fin and the second fin;
removing portions of the first fin and the second fin on both sides of the gate;
forming silicon germanium tops on the first fin and the second fin in place of the portions;
removing the silicon germanium tops on the second fin; and
forming silicon phosphorous tops on the second fin in place of the silicon germanium tops.

10. The method according to claim 9, wherein the first fin is part of a p-type FinFET and the second fin is part of an n-type FinFET.

11. The method according to claim 9, further comprising:
forming a mask over the substrate, the first fin, the second fin, and the gate prior to removing the portions of the first fin and the second fin; and
removing a first portion of the mask to expose the portions of the first fin and the second fin.

12. The method according to claim 11, comprising:
forming the mask to a thickness of 10 nm.

13. The method according to claim 11, further comprising:
forming a cap over the gate prior to forming the mask;
forming the mask over the cap; and
removing the mask over the gate and part of the cap during removal of the first portion of the mask.

14. The method according to claim 9, further comprising:
forming a mask over the silicon germanium tops of the first fin and the second fin; and
removing a first portion of the mask to expose the silicon germanium tops on the second fin prior to removing the silicon germanium tops on the second fin.

15. The method according to claim 15, comprising:
forming the mask to a thickness of 3 nm.

16. The method according to claim 9, wherein the silicon phosphorous tops of the second fin are smaller than the silicon germanium tops of the first fin.

17. An apparatus comprising:
a substrate;
a first fin and a second fin extending up from the substrate; and
a gate crossing over the first fin and the second fin above the substrate, the gate having a planar top surface,
wherein top ends of the first fin on both sides of the gate comprise silicon germanium, and top ends of the second fin on both sides of the gate comprise silicon phosphorous.

18. The apparatus according to claim 17, further comprising:
a diffusion liner below the top ends of the first fin and the second fin.

19. The apparatus according to claim 17, wherein the silicon germanium top ends of the first fin are larger than the silicon phosphorous top ends of the second fin.

20. The apparatus according to claim 19, wherein the silicon germanium top ends of the first fin include a high-doped germanium first layer and a low-doped germanium second layer, and the low-doped germanium second layer is also below the silicon phosphorous top ends of the second fin.
